(19) United States
(12) Patent Application Publication
(10) Pub. No.: US 2024/0186161 A1
(43) Pub. Date: Jun. 6, 2024

(54) SUBSTRATE PROCESSING METHOD, THERMAL PROCESSING APPARATUS, AND SEMICONDUCTOR MANUFACTURING EQUIPMENT

(71) Applicant: SEMES CO., LTD., Cheonan-si (KR)

(72) Inventors: Sung Yong LEE, Cheonan-si (KR); Myung Hwan OH, Cheonan-si (KR); Sung Kyu PARK, Cheonan-si (KR)

(73) Assignee: SEMES CO., LTD., Cheonan-si (KR)

(21) Appl. No.: 18/524,241

(22) Filed: Nov. 30, 2023

(30) Foreign Application Priority Data
Dec. 1, 2022 (KR) 10-2022-0165526

(51) Int. Cl. H01L 21/67; H01L 21/324; H01L 21/66

(52) U.S. Cl. CPC H01L 21/67248; H01L 21/324; H01L 21/67109; H01L 22/26

(57) ABSTRACT

Disclosure provides a substrate processing method, a thermal processing apparatus, and semiconductor manufacturing equipment that allow wafer thermal processing to be uniformly performed at a preset temperature. The substrate processing method includes determining an output of a heater provided in a heating plate by using a sensor substrate including a plurality of substrate temperature sensors, and performing thermal processing with respect to a substrate in response to the output of the heater. The determining of the output of the heater includes heating the sensor substrate through an initial output of the heater, measuring temperature distribution of the sensor substrate, determining the amount of change of target temperature distribution of the heating plate, and adjusting the output of the heater in response to the amount of change of the target distribution of the temperature heating plate.

### CROSS REFERENCE TO RELATED APPLICATION

The present application claims priority to Korean Patent Application No. 10-2022-0165526, filed Dec. 1, 2022, the entire contents of which are incorporated herein for all purposes by this reference.

### BACKGROUND OF THE INVENTION

### Field of the Invention

The present disclosure relates to a substrate processing method, a thermal processing apparatus, and semiconductor manufacturing equipment.

### Description of the Related Art

A semiconductor manufacturing process is a process of manufacturing a final product through several tens to hundreds of steps on a substrate (wafer). Each process may be performed by manufacturing equipment that performs the process. During the semiconductor manufacturing process, a coating process in which a liquid film is formed on a substrate is applied before a light exposure (lithography) process that is for forming a pattern on the substrate. After a liquid film is formed on the substrate, and after light exposure, a heat treatment process (or a bake process) in which heat energy is applied to the substrate is performed. In the thermal treatment process, thermal energy is applied to a substrate from a heating plate that supports the substrate below the substrate. At this point, it is important to uniformly apply thermal energy to the entire region of the substrate.

Specifically, since a predetermined gap exists between the substrate and the heating plate, the temperature of the heating plate is not directly transmitted to the substrate and the temperature of each region may not be uniform due to conditions such as an internal structure of the bake unit, air flow, etc. Therefore, in order to perform wafer thermal processing uniformly at a preset temperature, it is important to preset the temperature of the heating plate when a thermal processing apparatus (e.g., bake unit) is initially installed.

### SUMMARY OF THE INVENTION

The present disclosure is intended to provide a substrate processing method, a thermal processing apparatus, and semiconductor manufacturing equipment that allow wafer thermal processing to be uniformly performed at a preset temperature.

According to the present disclosure, a substrate processing method includes: determining an output of a heater provided in a heating plate by using a sensor substrate including a plurality of substrate temperature sensors; and performing thermal processing with respect to a substrate in response to the output of the heater. The determining of the output of the heater may include: heating the sensor substrate through an initial output of the heater; measuring temperature distribution of the sensor substrate; determining the amount of change of target temperature distribution of the heating plate, on the basis of a deviation of the measured temperature distribution of the sensor substrate and target temperature distribution of the sensor substrate and a transfer coefficient defining change in temperature of each temperature control region in the sensor substrate according to change in temperature of a specific heating region in the heating plate; and adjusting the output of the heater in response to the amount of change of the target temperature distribution of the heating plate.

The amount of change of the target temperature distribution of the heating plate is determined through the equation described below.

ΔT_{Heater}=KΔT_{wafer (K=(F}_{^{T}}_{F)}_{^{−1}}_{F}_{^{T}}₎

ΔT_{Heater} corresponds to the amount of change of the target temperature distribution of the heating plate, and F is a matrix composed of the transfer coefficient, and ΔT_{wafer} corresponds to the measured temperature distribution of the sensor substrate and the deviation of the target temperature distribution of the sensor substrate.

The determining of the amount of change of the target temperature distribution of the heating plate may include calculating a vector of a target temperature change value for each heating region of the heating plate to minimize a deviation of a vector of an expected temperature change value for each temperature control region of the sensor substrate, which is calculated by multiplying a matrix of the transfer coefficient and the vector of the target temperature change value for each heating region of the heating plate, and a vector of a target temperature change value for each temperature control region.

The temperature adjustment region of the sensor substrate may correspond to a location of each substrate temperature sensor measuring temperature of the sensor substrate.

The transfer coefficient may be defined by experimental data obtained by measuring change in the temperature distribution of the sensor substrate according to change in temperature for each heating region of the heating plate.

The substrate processing method may include: measuring the temperature distribution of the sensor substrate heated according to adjusted output of the heater, determining whether or not the measured temperature distribution of the sensor substrate is included in a criteria range by comparing the measured temperature distribution of the sensor substrate and the target temperature distribution of the sensor substrate; and re-adjusting the amount of change of the target temperature distribution of the heating plate when the measured temperature distribution of the sensor substrate is deviated from the criteria range.

The substrate processing method may include: updating the transfer coefficient in response to the measured temperature distribution of the sensor substrate and the deviation of the target temperature distribution of the sensor substrate.

According to the present disclosure, a thermal processing apparatus configured to perform thermal processing includes: a heating plate provided in a circular shape to allow a substrate to be seated; a heater configured to emit heat to heat the substrate; a plate temperature sensor configured to measure temperature of the heating plate; and a controller configured to control an output of the heater. The controller may be preset to determine an output of the heater by using a sensor substrate including a plurality of substrate temperature sensors, and to perform thermal processing with respect to the substrate in response to the output of the heater. In order to determine the output of the heater, the controller may be preset to heat the sensor substrate located at the heating plate through the heater, to obtain measured temperature distribution of the sensor substrate, to determine the amount of change of target temperature distribution of the heating plate, on the basis of a deviation of the measured temperature distribution of the sensor substrate and target temperature distribution of the sensor substrate, and a transfer coefficient defining change in temperature of each temperature control region in the sensor substrate according to change in temperature of a specific heating region in the heating plate, and to determine the output of the heater in response to the amount of change of the target temperature distribution of the heating plate.

According to the present disclosure, a semiconductor manufacturing equipment includes: an index module configured to transfer a substrate from a container in which the substrate is received; and a processing module including a bake unit performing thermal processing with respect to the substrate. The bake unit may include: a heating plate provided in a circular shape to allow a substrate to be seated; a heater configured to emit heat to heat the substrate; a plate temperature sensor configured to measure temperature of the heating plate; and a controller configured to control an output of the heater. The controller may be preset to determine an output of the heater by using a sensor substrate including a plurality of substrate temperature sensors, and to be preset to perform thermal processing with respect to the substrate in response to the output of the heater. In order to determine the output of the heater, the controller may be preset to heat the sensor substrate located at the heating plate through the heater, to measure temperature distribution of the sensor substrate, to determine the amount of change of target temperature distribution of the heating plate, on the basis of a deviation of the measured temperature distribution of the sensor substrate and target temperature distribution of the sensor substrate, and a transfer coefficient defining change in temperature of each temperature control region in the sensor substrate according to change in temperature of a specific heating region in the heating plate, and to determine the output of the heater in response to the amount of change of the target temperature distribution of the heating plate.

According to the present disclosure, thermal processing can be uniformly performed by determining the amount of change of target temperature distribution of the heating plate to minimize a temperature deviation of the sensor substrate by using the transfer coefficient.

### BRIEF DESCRIPTION OF THE DRAWINGS

FIG. 1 is a view showing the exterior shape of semiconductor manufacturing equipment to which the present disclosure may be applied.

FIG. 2 is a view showing a schematic layout of the semiconductor manufacturing equipment.

FIG. 3 is a view showing a coating block of the semiconductor manufacturing equipment.

FIG. 4 is a view showing a state in which a sensor substrate is seated on a heating plate for setting the temperature in a thermal processing apparatus according to the present disclosure.

FIG. 5 is a view showing a state in which a substrate to which thermal processing is performed in the thermal processing apparatus according to the present disclosure is seated.

FIG. 6 is a view showing heating region of the heating plate in a bake unit according to the present disclosure.

FIG. 7 is a view showing an example of arrangement of plate temperature sensors that measure the temperature of the heating plate in the bake unit according to the present disclosure.

FIG. 8 is a view showing an example of arrangement of the substrate temperature sensors that measure the temperature of the sensor substrate in the bake unit according to the present disclosure.

FIG. 9 is a view showing an example of a substrate temperature change model according to the present disclosure.

FIG. 10 is a flowchart showing a substrate processing method according to the present disclosure.

FIGS. 11 and 12 are flowcharts showing a process of determining an output of a heater in the substrate processing method according to the present disclosure.

### DETAILED DESCRIPTION OF THE DISCLOSURE

Hereinbelow, exemplary embodiments of the present disclosure will be described in detail with reference to the accompanying drawings such that the present disclosure can be easily embodied by one of ordinary skill in the art to which the present disclosure belongs. The present disclosure may be changed to various embodiments and the scope and spirit of the present disclosure are not limited to the embodiments described hereinbelow.

In the following description, if it is decided that the detailed description of known function or configuration related to the present disclosure makes the subject matter of the present disclosure unclear, the detailed description is omitted, and the same reference numerals will be used throughout the drawings to refer to the elements or parts with same or similar function or operation.

Furthermore, in various embodiments, an element with same configuration will be described in a representative embodiment by using the same reference numeral, and different configuration from the representative embodiment will be described in other embodiment.

Other words used to describe the relationship between elements should be interpreted in a like fashion such as “between” versus “directly between”, “adjacent” versus “directly adjacent”, etc. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

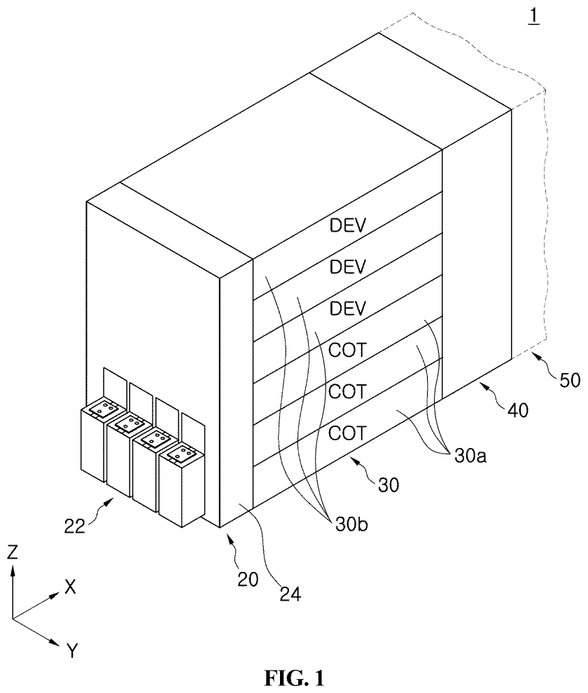

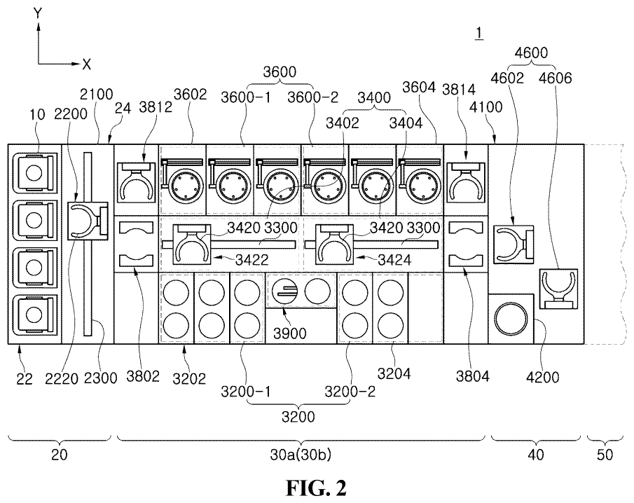

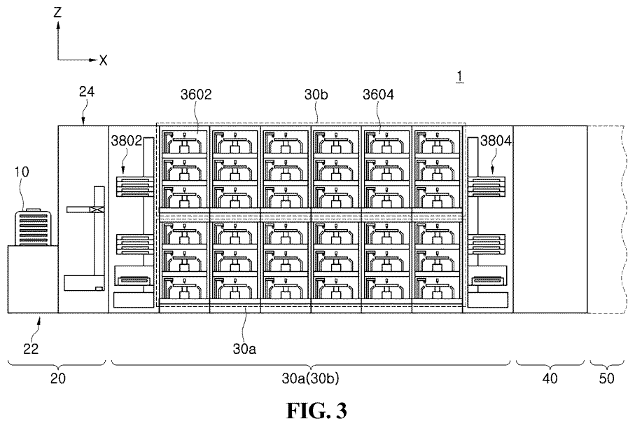

FIG. 1 is a view showing the exterior shape of semiconductor manufacturing equipment 1 to which the present disclosure may be applied. FIG. 2 is a view showing a schematic layout of the semiconductor manufacturing equipment 1. FIG. 3 is a view showing a coating block 30a of the semiconductor manufacturing equipment 1. FIGS. 1 to 3 show photo spinner equipment performing coating processing and developing processing of photo resist liquid for light exposure processing, as an example of the semiconductor manufacturing equipment 1. However, the present disclosure is not limited to the photo spinner equipment and may be applied to different varieties of equipment performing thermal processing.

Referring to FIGS. 1 to 3, the semiconductor manufacturing equipment 1 includes an index module 20 transfer a substrate W such as a wafer from a container 10 where the substrate W is stored, a processing module 30 performing a coating process and a developing process with respect to the substrate W and including a bake unit 3200 performing thermal processing with respect to the substrate W, and an interface module 40 connecting the processing module 30 to external light exposure equipment 50.

The index module 20, the processing module 30, and the interface module 40 may be sequentially arranged. Hereinbelow, a direction in which the index module 20, the processing module 30, and the interface module 40 are arranged is referred to as a first horizontal direction X, and a direction perpendicular to the first horizontal direction X when viewed from the upper side is referred to as a second horizontal direction X, and a direction perpendicular to both the first direction X and the second horizontal direction X is referred to as a vertical direction Z.

The index module 20 transfers the substrate W from the container 10 where the substrate W is received to the processing module 30, and stores the substrate W of which processing is completed into the container 10. A longitudinal direction of the index module 20 is provided as the second horizontal direction X. The index module 20 may include a load port 22 and an index frame 24. Based on the index frame 24, the load port 22 is located at the opposite side to the processing module 30. Containers 10 in which substrates W are stored are placed on the load port 22. The load port 22 may include a plurality of load ports 22, and the plurality of the load ports 22 may be arranged in the second horizontal direction X.

An airtight container 10 such as a front open unified pod (FOUP) may be used as the container 10. The container 10 may be a transfer means (not shown) such as an overhead transfer, an overhead conveyor, or an automatic guided vehicle but may be placed on each load port 22 by an operator.

An index robot 2200 driven in an index transfer section 2100 is provided in the index frame 24. The index frame 24 includes a guide rail 2300 provided in the second horizontal direction X as a longitudinal direction thereof, and the index robot 2200 may be provided to be movable on the guide rail 2300. The index robot 2200 includes a hand 2220 on which the substrate W is placed, and the hand 2220 may be provided to be movable forwards and rearwards, rotatable in the vertical direction Z, and movable in the vertical direction Z.

The processing module 30 may perform the coating process and the developing process with respect to the substrate W.

The processing module 30 includes a coating block 30a and a developing block 30b. The coating block 30a performs the coating process with respect to the substrate W, and the developing block 30b performs the developing process with respect to the substrate W. The coating block 30a includes a plurality of coating blocks 30a, and the plurality of coating blocks 30a is provided to be stacked with each other. The developing block 30b includes a plurality of developing blocks 30b, and the plurality of developing blocks 30b is provided to be stacked with each other.

According to the embodiment of FIG. 1, the coating block 30a includes 3 coating blocks 30a, and the developing block 30b includes 3 developing blocks 30b. The coating blocks 30a may be respectively arranged below the developing blocks 30b. As an example, the 3 coating blocks 30a perform the same process, and may be provided with the same structure. Furthermore, the 3 developing blocks 30b perform the same process, and may be provided with the same structure. However, in the semiconductor manufacturing equipment 1 to which the present disclosure may be applied, arrangement and configuration of the coating blocks 30a and the developing blocks 30b may not be limited to the structure shown in FIG. 1, and diverse changes may be applied thereto.

Referring to FIG. 2, each coating block 30a includes a bake unit 3200, a transfer unit 3400, and a liquid processing unit 3600.

The transfer unit 3400 serves to transfer the substrate W between the bake unit 3200 and the liquid processing unit 3600 in each coating block 30a. The transfer unit 3400 may include a first transfer section 3402 as a first movement path, and a second transfer section 3404 as a second movement path. The first and second transfer sections 3402 and 3404 have a longitudinal direction provided in parallel with the first horizontal direction X and are connected to each other. The first, second transfer robot 3422, 3424 is provided in the first, second transfer section 3402, 3404.

As an example, the first, second transfer robot 3422, 3424 has a robot hand 3420 on which the substrate W is placed, and the robot hand 3420 may be provided to be movable forwards and rearwards, rotatable in the vertical direction Z, movable along the vertical direction Z. A guide rail 3300 is provided in first, second transfer section 3402, 3404 provided in parallel to the first horizontal direction X, and the transfer robot 3422, 3424 may be provided to be movable on the guide rail 3300.

Referring to FIG. 2, the first, second transfer section 3402, 3404 may be provided with the same structure. The first transfer section 3402 is located closer to the index module 20, and the second transfer section 3404 is located closer to the interface module 40.

The bake unit 3200 performs a thermal treatment process with respect to the substrate W. The bake unit 3200 corresponds to an example of a thermal processing device to be described below. The thermal treatment process may include a cooling process and a heating process. The liquid processing unit 3600 supplies liquid on the substrate W to form a liquid film. The liquid film may be a photoresist film and an antireflection film.

The liquid processing unit 3600 may include a first liquid processing part 3600-1 having liquid processing chambers coating an antireflection film on the substrate W, and a second liquid processing part 3600-2 having liquid processing chambers coating a photoresist film on the substrate W coated with the antireflection film. The first liquid processing part 3600-1 is arranged at one side of the first transfer section 3402, and the second liquid processing part 3600-2 is arranged at one side of the second transfer section 3404.

The liquid processing unit 3600 has a plurality of liquid processing chambers 360, 3604. The plurality of liquid processing chambers 360, 3604 may be arranged in a longitudinal direction of the transfer unit 3400. Furthermore, some of the plurality of liquid processing chambers 360, 3604 may be provided to be stacked with each other.

The bake unit 3200 may include a first bake unit 3200-1 having thermal processing chambers 3202 in which thermal processing is performed to substrates W for the antireflection film coating, and a second bake unit 3200-2 having thermal processing chambers 3204 in which thermal processing is performed to substrates W for photoresist coating. The first bake unit 3200-1 is arranged at one side portion of the first transfer section 3402, and the second bake unit 3200-2 is arranged at one side portion of the second transfer section 3404. The thermal processing chambers 3202 arranged at the side portion of the first transfer section 3402 are called front end thermal processing chambers, and the thermal processing chambers 3204 arranged at the side portion of the second transfer section 3404 are called rear end thermal processing chambers.

In other words, the first liquid processing part 3600-1 and the first bake unit 3200-1 for forming the antireflection film on a substrate W are arranged at the first transfer section 3402, and the second liquid processing part 3600-2 and the second bake unit 3200-2 for forming a photoresist film on a substrate W are arranged at the second transfer section 3404.

Meanwhile, the processing module 30 includes a plurality of buffer chambers 3802, 3804. Among the plurality of buffer chambers 3802, 3804, a partial buffer chamber 3802 is arranged between the index module 20 and the transfer unit 3400. The buffer chamber 3802 may be called a front end buffer chamber 3802. The buffer chamber 3802, 3804 includes a plurality of buffer chambers to be located to be stacked with each other in the vertical direction Z. Among the plurality of buffer chambers 3802, 3804, another partial buffer chamber 3804 is arranged between the transfer unit 3400 and the interface module 40. The buffer chamber 3804 may be called a rear end buffer chamber 3804. The rear end buffer chamber 3804 includes a plurality of buffer chambers to be located to be stacked with each other in the vertical direction Z. Each of the front end buffer chamber 3802 and the rear end buffer chamber 3804 serves to store temporarily a plurality of substrates W. Meanwhile, the plurality of buffer chambers 3802, 3804 may include buffer transfer robots 3812, 3814 to transfer a substrate W.

An interface buffer 4100 provides a space in which the substrate W transferred between each coating block 30a, an additional process chamber 4200, the light exposure equipment 50, and each developing block 30b temporarily stays during transferring. The interface buffer 4100 includes a plurality of interface buffers 4100, and the plurality of interface buffers 4100 may be provided to be stacked with each other.

A transfer member 4600 serves to transfer a substrate W between the coating block 30a, the additional process chamber 4200, the light exposure equipment 50, and the developing block 30b. The transfer member 4600 may consist of 1 more robots. As an example, the transfer member 4600 may include a first interface robot 4602 and a second interface robot 4606.

The first interface robot 4602 may transfer a substrate W between the coating block 30a, the additional process chamber 4200, and the interface buffer 4100. The second interface robot 4606 may transfer a substrate W between the interface buffer 4100 and the light exposure equipment 50.

All hands of the index robot 2200, the first interface robot 4602, and the second interface robot 4606 may be provided to have the same shape as the robot hand 3420 of the transfer robot 3422, 3424. Selectively, a hand of a robot directly exchanging a substrate W with a transfer plate of the thermal processing chamber is provided to have the same shape as the robot hand 3420 of the transfer robot 3422, 3424, and hands of remaining robots may be provided to have different shapes therefrom.

Referring to FIG. 2 again, a cooling transfer module 3900 is provided for transfer of substrate W and cooling of substrate W between the first transfer robot 3422 and the second transfer robot 3424. The cooling transfer module 3900 is arranged at the bake unit 3200 adjacent to a boundary where the first movement path of the first transfer robot 3422 and the second movement path of the second transfer robot 3424 meet each other. The cooling transfer module 3900 may be arranged to be stacked in a multistage manner like the thermal processing chamber.

Hereinbelow, according to the present disclosure, a substrate processing method, a thermal processing apparatus, and the semiconductor manufacturing equipment 1 including the same will be described. According to the present disclosure, the thermal processing apparatus may correspond to the bake unit 3200 of the semiconductor manufacturing equipment 1. However, the present disclosure is not limited to temperature control of the bake unit 3200 and may be applied to various process that perform thermal processing with respect to the substrate W.

At the initial stage when a semiconductor manufacturing equipment like the semiconductor manufacturing equipment 1 is installed in a semiconductor manufacturing factory, or when the thermal processing apparatus (the bake unit 3200) is reset for maintenance, the temperature of a heating plate 100 that heats the substrate W in the thermal processing apparatus is preset. The temperature of the heating plate 100 is preset by adding an offset considering a thermal loss between the substrate W and the heating plate 100 to a target temperature for thermal processing of the substrate W. In other words, the usual preset temperature of the heating plate 100 is determined as a value obtained by adding to the target temperature of the substrate W.

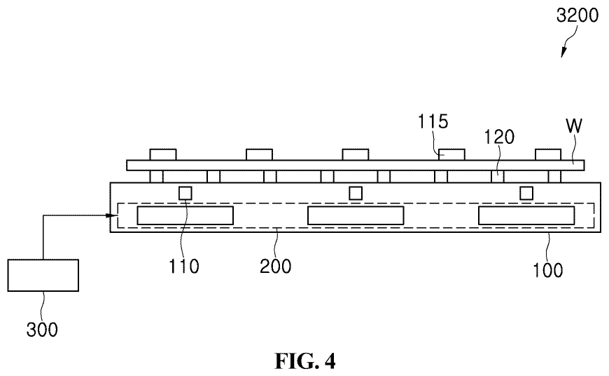

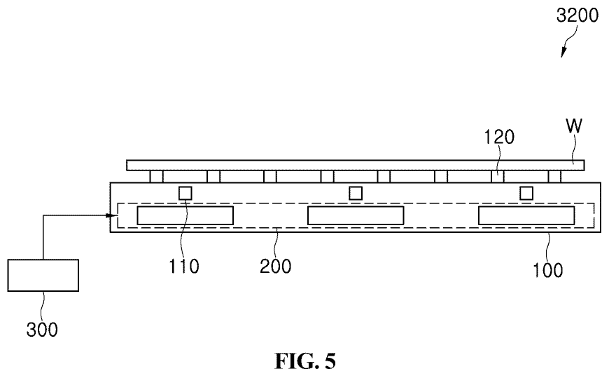

FIG. 4 is a view showing a state in which the sensor-type substrate W is seated on the heating plate for setting the temperature in the thermal processing apparatus (e.g., the bake unit 3200) according to the present disclosure. FIG. 5 is a view showing a state in which the substrate W to which thermal processing is performed in the thermal processing apparatus according to the present disclosure is seated.

Referring to FIGS. 4 and 5, the thermal processing apparatus includes the heating plate 100 having a circular shape so that the substrate W is seated on an upper portion thereof, a heater 200 embedded in the heating plate 100 and emitting heat to heat the substrate W, a plate temperature sensor 110 embedded in the heating plate 100 and measuring the temperature, and a controller 300 supplying power applied to the heater 200 in response to an output value of the heater. The substrate W may be seated on a support pin 120 provided at the upper portion of the heating plate 100. Referring to FIG. 4, a sensor substrate SW corresponding to the sensor-type substrate W is located at the heating plate 100 for controlling the temperature of the bake unit 3200, and as heat is applied to the sensor substrate SW from the heating plate 100, the temperature of the substrate W is measured by a substrate temperature sensor 115 of the substrate W. As shown in FIG. 4, when the desired temperature distribution is achieved as a result of measuring the temperature by using the substrate temperature sensor 115, as shown in FIG. 5, the thermal treatment process may be actually performed with respect to the substrate W. The temperature control method of the present disclosure may be applied to a process of determining an output value of the heater 200 for achieving the desired temperature distribution on the sensor substrate SW while applying heat to the sensor substrate SW from the heater 200 provided in the heating plate 100, as shown in FIG. 5 However, this is only one embodiment, and the temperature control method of the present disclosure may be applied to a process of adjusting the temperature in the thermal treatment process with respect to the substrate W.

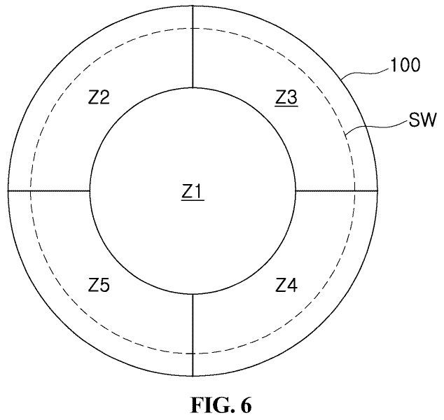

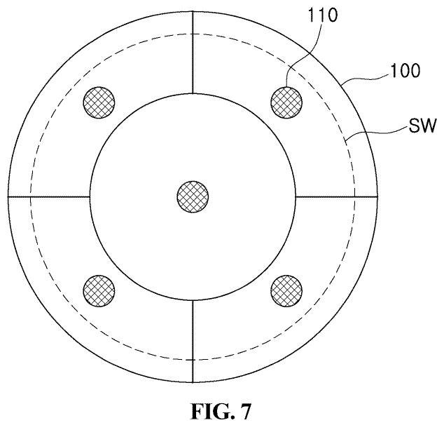

According to the present disclosure, in order to perform precise control of the temperature distribution of the substrate W and the sensor substrate SW, the heating plate 100 may be divided into a plurality of heating regions. For example, as shown in FIG. 6, the heating plate 100 may be divided into fifth heating regions of a center region Z1, a left-upper region Z2, a right-upper region Z3, a right-lower region Z4, and a left-lower region Z5. Each heater 200 is provided for each heating region, and each plate temperature sensor 110 may be provided to measure the temperature of each heating region. As shown in FIG. 7, each plate temperature sensor 110 is located for each heating region and may measure the temperature each heating region. FIG. 6 shows the heating plate 100 divided into 5 regions, but the number of heating regions and a dividing method of the heating plate 100 may be variable.

When the heating plate 100 is heated through the heater 200, heat of the heating plate 100 is transmitted to the substrate W. Considering a gap between the heating plate 100 and the substrate W, the temperature of the heating plate 100 is preset to be higher than the target temperature of the substrate W by a predetermined offset. However, by an internal structure of the thermal processing apparatus or an external factor such as an air flow, the temperature distribution of the substrate W may not be constant. Since the temperature of thermal processing of the substrate W needs to be uniform in the thermal treatment process, the heating plate 100 and the heater 200 are respectively divided into a plurality of heating regions, and an output of each heating region may be further precisely controlled in the present disclosure. The embodiment of the present disclosure provides a method for further precisely controlling the temperature of each heating region of the heating plate 100 in order to achieve the desired temperature distribution throughout the entire regions of the substrate W.

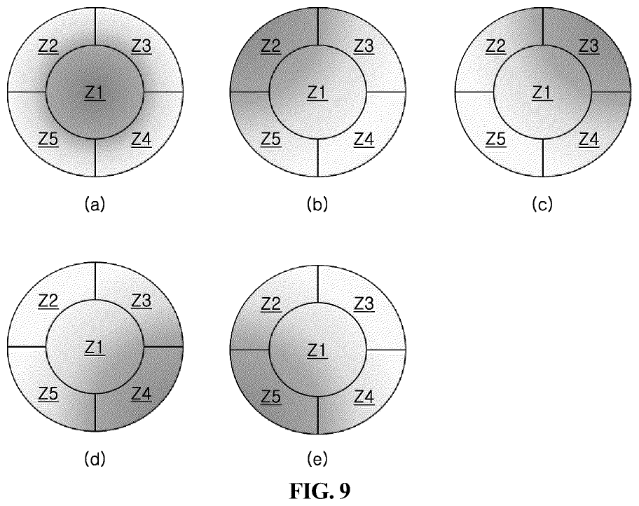

First, according to the present disclosure, a substrate temperature change model defines change in the temperature of the substrate W in response to change in the temperature for each heating region of the heating plate 100. FIG. 9 is a view showing an example of the substrate temperature change model according to the present disclosure. In FIG. 9, a light region represents an initial temperature and as a region becomes darker the variation represents an increase degree of the temperature. As shown in FIG. 9, it can be confirmed that as the temperature increase occurs in a specific heating region of the heating plate 100, the temperature increase is dispersed to other regions of the substrate W. In other words, when the temperature of a partial heating region is changed in order to increase the temperature of a specific region of the substrate W, the temperature of the surrounding region of the substrate W may be changed so that temperature control for each heating region of the heating plate 100 need to be performed considering the temperature distribution of the entire substrate W. The substrate temperature change model may be configured through experimental data or simulation.

According to the present disclosure, the temperature control method includes configuring the substrate temperature change model, and defining a transfer coefficient indicating transfer of the temperature from the heating plate 100 to the substrate W in the substrate temperature change model, obtaining the temperature distribution of the heating plate 100 to minimize a deviation of the temperature distribution of the substrate W by using an optimization logic (e.g., least-square method (LSM), and calculating an offset value achieving the temperature distribution of the heating plate 100. Hereinbelow, the temperature control method for thermal processing of the substrate W according to the present disclosure will be described in detail. Hereinbelow, the temperature control method to be described below will be performed by the controller 300.

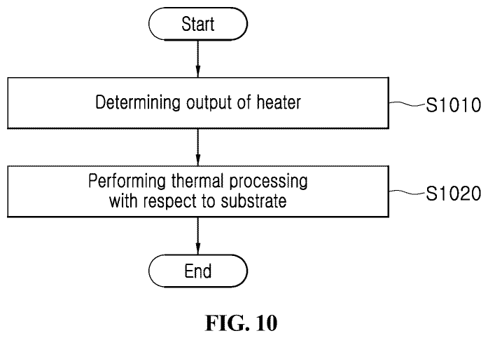

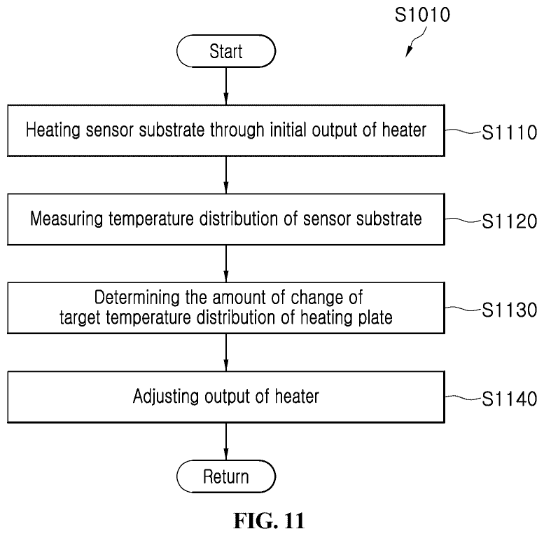

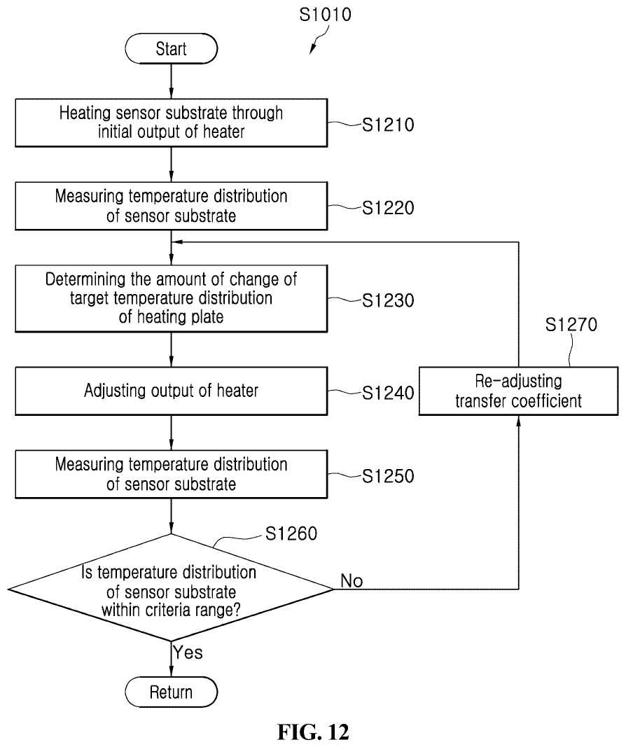

FIG. 10 is a flowchart showing a substrate processing method according to the present disclosure. FIGS. 11 and 12 are flowcharts showing a process of determining an output of a heater in the substrate processing method according to the present disclosure.

According to the present disclosure, the substrate processing method includes determining an output of the heater 200 provided in the heating plate 100 by using the sensor substrate SW including a plurality of substrate temperature sensors 115 at S1010, and performing thermal processing with respect to the substrate W in response to the output of the heater 200 at S1020. The determining of an output of the heater at S1010 includes heating the sensor substrate SW through an initial output of the heater 200 at S1110, measuring the temperature distribution of the sensor substrate SW at S1120, determining the amount of change of target temperature distribution of the heating plate 100, on the basis of a deviation of the measured temperature distribution of the sensor substrate SW and the target temperature distribution of the sensor substrate SW and a transfer coefficient defining change in the temperature of each temperature control region in the sensor substrate SW in response to change in the temperature of a specific heating region in the heating plate 100, at S1130, and adjusting an output of the heater 200 in response to the amount of change of the target temperature distribution of the heating plate 100 at S1140.

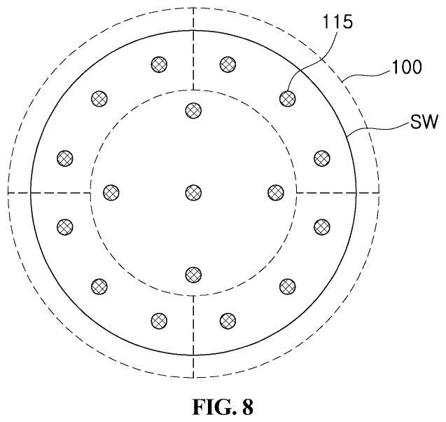

In the heating of the substrate W initially at S1110, a temperature obtained by adding an initial offset to the target temperature value of the sensor substrate SW is applied to the heating plate 100. For example, when the target temperature of the sensor substrate SW is 80° C., the temperature of each heating region of the heating plate 100 may be preset to 85° C. After heat is applied to the sensor substrate SW for a predetermined time through the heating plate 100 to which the initial temperature is applied, in S1120, whether or not the temperature distribution of the sensor substrate SW satisfies criteria is determined by measuring the temperature distribution of the sensor substrate SW. As shown in FIGS. 4 and 8, the temperature of each temperature control region of the sensor substrate SW is measured by each substrate temperature sensor 115 provided in the sensor substrate SW. Whether or not the temperature of the sensor substrate SW is within a predetermined range (e.g., 0.1° C.) from a reference temperature (e.g., 80° C.) may be determined by measuring the temperature of each temperature control region. When the temperature distribution of the sensor substrate SW satisfies a criteria, the substrate W to which processing is actually performed is inserted into the thermal processing apparatus and then thermal processing with respect to the substrate W is performed.

When the temperature distribution of the sensor substrate SW does not satisfy the criteria, an output of the heater for thermal processing is performed. During the heater output adjusting process for thermal processing, adjustment of an offset value for each heating region of the heating plate 100 may be performed.

The amount of change of the target temperature distribution of the heating plate 100 is determined to minimize a deviation of expected temperature distribution of the sensor substrate SW obtained by applying the transfer coefficient to the target temperature distribution of the heating plate 100. The transfer coefficient is determined by the substrate temperature change model that defines change in the temperature distribution of the substrate W in response to change in the temperature for each heating region of the heating plate 100.

According to the present disclosure, the determining of the amount of change of the target temperature distribution of the heating plate 100 at S1130 includes calculating an offset added to the target temperature distribution of the sensor substrate SW, and adjusting an offset to minimize a deviation of the target temperature distribution and the expected temperature distribution of the sensor substrate SW. Since a predetermined gap exists between the heating plate 100 and the sensor substrate SW, heat is applied to the heating plate 100 with a temperature value obtained by adding an offset value to a value of the target temperature of the sensor substrate SW. Then, a difference between the measured temperature distribution and the target temperature distribution of the sensor substrate SW is calculated by measuring the temperature distribution of the sensor substrate SW, and an offset value may be adjusted in order to minimize a difference between the measured temperature distribution and the target temperature distribution of the sensor substrate SW. In the specification, the determining of the target temperature distribution of the heating plate 100 (i.e., determining of output of the heater 200) may be equivalent to determining of an offset value.

According to the present disclosure, according to the substrate temperature change model, the target temperature distribution of the heating plate 100 may be determined to minimize the expected temperature distribution of the sensor substrate SW in response to change in the temperature of the heating plate 100 and the target temperature distribution of the sensor substrate SW. According to the embodiment of the present disclosure, by a least square method (LSM), the target temperature distribution (temperature for each heating region) of the heating plate 100 may be determined so as to minimize the expected deviation of temperature distribution of the sensor substrate SW and the target temperature distribution of the sensor substrate SW.

For example, the target temperature of the sensor substrate SW is defined as Twafer, the target temperature of the heating plate 100 is defined as Theater, the transfer coefficient, that is, relationship between the temperature of the heating plate 100 and the temperature of the sensor substrate SW may be defined as F. At this point, the target temperature (Tₕₑₐₜₑᵣ) of the heating plate 100 may be determined as a value minimizing the target temperature of the sensor substrate SW and the expected deviation of temperature of the sensor substrate SW as shown in Equation 1.

$${min}_{{T}_{heater}} ‖ {T}_{wafer} - {FT}_{heater} ‖ \qquad [ Equation 1 ]$$

At this point, Twafer a vector composed of a target temperature value (T_{w1}, T_{w2}, . . . T_{wm}) of m temperature control regions of the sensor substrate SW, Theater is a vector composed of a target temperature value (Tₕ₁, Tₕ₂, . . . Tₕₙ) for n heating regions of the heating plate 100, F is a m×n matrix (m is the number of rows, n is the number of columns) composed of the transfer coefficient indicating a degree of temperature transmission between each heating region of the heating plate 100 and each temperature control region of the sensor substrate SW. A target temperature value for each heating region of the heating plate 100 is a value obtained by adding an offset value to a target temperature value of the sensor substrate SW, and each offset value may be determined to minimize the deviation of the target temperature distribution and the expected temperature distribution of the sensor substrate SW. For example, when the heating plate 100 has 5 heating regions as shown in FIG. 7, n is 5 (n=5), and when 16 substrate temperature sensors 115 measuring the temperature of the sensor substrate SW are provided as shown in FIG. 8, the sensor substrate SW has 16 temperature control regions and thus m is 16 (m=16). At this point, the number (n) of the heating regions of the heating plate 100 and the number (m) of the temperature control regions of the sensor substrate SW may be configured to be sufficiently variable.

In other words, the determining of the amount of change of the target temperature distribution of the heating plate 100 at S1130 includes calculating a vector (T_{Heater}) of a target temperature change value for each heating region of the heating plate 100 to minimize a deviation of a vector (F*T_{Heater}) of an expected temperature change value for each temperature control region of the sensor substrate SW, the expected temperature change value being calculated by multiplying a matrix F of the transfer coefficient and the vector (T_{Heater}) of the target temperature change value for each heating region of the heating plate 100, and a vector (T_{wafer}) of a target temperature change value for each temperature control region.

According to the substrate temperature change model of the present disclosure, the temperature distribution of the sensor substrate SW may be defined as shown in Equation 2.

$$[ \begin{matrix}{T}_{w 1} \\ ⋮ \\ {T}_{wm}\end{matrix} ] = [ \begin{matrix}{F}_{1 , 1} & … & {F}_{1 , n} \\ ⋮ & ⋱ & ⋮ \\ {F}_{m , 1} & … & {F}_{m , n}\end{matrix} ] [ \begin{matrix}{T}_{h 1} \\ ⋮ \\ {T}_{hn}\end{matrix} ] \qquad [ Equation 2 ]$$

The amount of change of the expected temperature distribution of the sensor substrate SW and the amount of change of the temperature distribution of the heating plate 100 may be defined as shown in Equation 3.

$$[ \begin{matrix}Δ {T}_{w 1} \\ ⋮ \\ Δ {T}_{wm}\end{matrix} ] = [ \begin{matrix}{F}_{1 , 1} & … & {F}_{1 , n} \\ ⋮ & ⋱ & ⋮ \\ {F}_{m , 1} & … & {F}_{m , n}\end{matrix} ] [ \begin{matrix}Δ {T}_{h 1} \\ ⋮ \\ Δ {T}_{hn}\end{matrix} ] \qquad [ Equation 3 ]$$

At this point, when a result of measuring the temperature distribution of the sensor substrate SW differs from the target temperature distribution, as shown in following Equation 4, the amount of change of the target temperature distribution of the heating plate 100 is calculated and the temperature of the heating plate 100 may be adjusted in response to the amount of change.

ΔT_{wafer}=F×ΔT_{Heater} F^{T}ΔT_{water=F}^{T}F×ΔT_{Heater} ΔT_{Heater}=(F^{T}F)⁻¹F^{T}ΔT_{wafer} ΔT_{Heater}=KΔT_{wafer (K=(F}_{^{T}}_{F)}_{^{−1}}_{F}_{^{T}}₎ [Equation 4]

According to the present disclosure, a temperature control region of the sensor substrate SW may correspond to a location of each substrate temperature sensor 115 measuring the sensor substrate SW.

ΔT_{Heater} corresponds to the amount of change of the target temperature distribution of the heating plate 100, F is a matrix composed of the transfer coefficient, ΔT_{wafer} corresponds to a deviation of the temperature distribution of the sensor substrate SW and the target temperature distribution of the sensor substrate SW.

According to the present disclosure, the substrate temperature change model may be composed of experimental data obtained by measuring the temperature distribution change of the sensor substrate SW in response to change in temperature for each heating region of the heating plate 100. In other words, the transfer coefficient may be defined by the experimental data obtained by measuring the temperature distribution change of the sensor substrate SW in response to change in temperature for each heating region of the heating plate 100.

Meanwhile, after the output of the heater is primarily adjusted, the temperature may be measured again, and in response to a result of temperature measurement, a process of re-adjusting an output value of the heater may be performed. Referring to FIG. 12, the determining of an output of the heater at S1010 includes heating the sensor substrate SW through an initial output of the heater 200 at S1210, measuring the temperature distribution of the sensor substrate SW at S1220, determining the amount of change of the target temperature distribution of the heating plate 100 on the basis of a deviation of the measured temperature distribution of the sensor substrate SW and the target temperature distribution of the sensor substrate SW and a transfer coefficient defining change in the temperature of each temperature control region in the sensor substrate SW in response to change in the temperature of a specific heating region in the heating plate 100 at S1230, and adjusting an output of the heater 200 in response to the amount of change of the target temperature distribution of the heating plate 100 at S1240.

Furthermore, the determining of the output of the heater at S1010 includes measuring the temperature distribution of the heated sensor substrate SW in response to the adjusted output of the heater 200 at S1250, determining whether or not the measured temperature distribution of the sensor substrate SW is included in a criteria range by comparing the measured temperature distribution of the sensor substrate SW and the target temperature distribution of the sensor substrate SW at S1260, and re-adjusting the amount of change of the target temperature distribution of the heating plate 100 when the measured temperature distribution of the sensor substrate SW is deviated from the criteria range. In other words, when the measured temperature distribution of the sensor substrate SW is deviated from the criteria range, S1230 is performed again and thus the amount of change of the target temperature distribution of the heating plate 100 may be determined again. At this point, the determining of output of the heater at S1010 includes updating the transfer coefficient in response to the deviation of the measured temperature distribution of the sensor substrate SW and the target temperature distribution of the sensor substrate SW, at S1270. In other words, despite output adjustment of the heater, when the temperature distribution of the sensor substrate SW is deviated from the criteria range, the amount of change of the target temperature distribution of the heating plate 100 may be determined again by using the updated transfer coefficient. The output of the heater may be determined again according to the amount of change of the target temperature distribution.

The temperature distribution of the heating plate 100 is defined by a temperature value for each heating region (Z1 to Z5) of the heating plate 100. The temperature distribution of the sensor substrate SW is defined as a temperature value measured by each substrate temperature sensor 115 provided in the sensor substrate SW. The output of the heater 200 means output (e.g., current, voltage, power, etc.) of the heater applied to each heating region Z1 to Z5 of the heating plate 100. The output of the heater for each heating region Z1 to Z5 of the heating plate 100 is determined by a target temperature value for each heating region Z1 to Z5 in response to pre-defined relationship.

According to the present disclosure, thermal processing of the substrate W may be performed by the thermal processing apparatus (e.g., the bake unit 3200) as shown in FIGS. 4 and 5. The thermal processing apparatus (the bake unit 3200) according to the present disclosure includes the heating plate 100 having a circular shape so that the substrate W may be seated on the upper portion, the heater 200 emitting heat for heating the substrate W, the plate temperature sensor 110 measuring the temperature of the heating plate 100, and the controller 300 controlling power applied to the heater 200.

The controller 300 is preset to determine output of the heater 200 by using the sensor substrate SW including the plurality of substrate temperature sensors 115, and to perform thermal processing with respect to the substrate W in response to the output of the heater 200.

In order to determine output of the heater 200, the controller 300 is preset to heat the sensor substrate SW located at the heating plate 100 by the heater 200; to obtained the measured temperature distribution of the sensor substrate SW; to determine the amount of change of the target temperature distribution of the heating plate 100, on the basis of a deviation of the measured temperature distribution of the sensor substrate SW and the target temperature distribution of the sensor substrate SW and the transfer coefficient defining temperature change of each temperature control region in the sensor substrate SW in response to temperature change of a specific heating region of the heating plate 100; and to determine output of the heater 200 in response to the amount of change of the target temperature distribution of the heating plate 100.

The amount of change of the target temperature distribution of the heating plate 100 is determined through the following Equation 5,

ΔT_{Heater}=KΔT_{wafer (K=(F}_{^{T}}_{F)}_{^{−1}}_{F}_{^{T}}₎ [Equation 5]

ΔT_{Heater} corresponds to the amount of change of the target temperature distribution of the heating plate 100, F is a matrix composed of the transfer coefficient, ΔT_{wafer} corresponds to a deviation of the temperature distribution of the sensor substrate SW and the target temperature distribution of the sensor substrate SW.

According to the present disclosure, the controller 300 is preset to calculate an offset added to the target temperature distribution of the sensor substrate SW, and to adjust the offset so as to minimize a deviation of the target temperature distribution and the expected temperature distribution of the sensor substrate SW.

According to the present disclosure, the controller 300 is preset to calculate a vector (F*Theater) of a target temperature change value for each heating region of the heating plate 100 to minimize a deviation of a vector (F*Tₕₑₐₜₑᵣ) of an expected temperature change value for temperature control region of the sensor substrate SW, which is calculated by multiplying the matrix F of the transfer coefficient and the vector (T_{Heater}) of the target temperature change value for each heating region of the heating plate 100, and a vector (T_{wafer}) of a target temperature change value for each temperature control region.

According to the present disclosure, a temperature control region of the sensor substrate SW corresponds to a location of each substrate temperature sensor 115 measuring the sensor substrate SW.

According to the present disclosure, the transfer coefficient is defined by the experimental data obtained by measuring the temperature distribution change of the sensor substrate SW in response to change in temperature for each heating region of the heating plate 100.

According to the present disclosure, the controller 300 is preset to measure the temperature distribution of the sensor substrate SW heated in response to the adjusted output of the heater 200, to determine whether or not the measured temperature distribution of the sensor substrate SW is within the criteria range by comparing the measured temperature distribution of the sensor substrate SW and the target temperature distribution of the sensor substrate SW, and to re-adjust the amount of change of the target temperature distribution of the heating plate when the measured temperature distribution of the sensor substrate SW is deviated from the criteria range.

According to the present disclosure, the controller 300 is preset to update the transfer coefficient in response to the deviation of the measured temperature distribution of the sensor substrate SW and the target temperature distribution of the sensor substrate SW.

Although the preferred embodiments of the present disclosure have been disclosed for illustrative purposes, those skilled in the art will appreciate that various modifications, additions and substitutions are possible, without departing from the scope and spirit of the invention as disclosed in the accompanying claims. Since the present disclosure may be embodied in other specific forms without changing the technical sprit or essential features, those skilled in the art to which the present disclosure belongs should understand that the embodiments described above are exemplary and not intended to limit the present disclosure.

The scope of the present disclosure will be defined by the accompanying claims rather than by the detailed description, and those skilled in the art should understand that various modifications, additions and substitutions derived from the meaning and scope of the present disclosure and the equivalent concept thereof are included in the scope of the present disclosure.

What is claimed is:

1. A substrate processing method comprising:
determining an output of a heater provided in a heating plate by using a sensor substrate comprising a plurality of substrate temperature sensors; and
performing thermal processing on a substrate in response to the output of the heater,
wherein the determining of the output of the heater comprises:
heating the sensor substrate through an initial output of the heater;
measuring temperature distribution of the sensor substrate;
determining an amount of change of target temperature distribution of the heating plate, on the basis of a deviation of the measured temperature distribution of the sensor substrate and a target temperature distribution of the sensor substrate, and a transfer coefficient defining change in temperature of each temperature control region in the sensor substrate according to change in temperature of a specific heating region in the heating plate; and
adjusting the output of the heater in response to the amount of change of the target temperature distribution of the heating plate.

2. The substrate processing method of claim 1, wherein the amount of change of the target temperature distribution of the heating plate is determined through the equation described below,
ΔT_{Heater}=KΔT_{wafer (K=(F}_{^{T}}_{F)}_{^{−1}}_{F}_{^{T}}₎
ΔT Heater corresponds to the amount of change of the target temperature distribution of the heating plate, and F is a matrix composed of the transfer coefficient, and ΔT_{wafer} corresponds to the measured temperature distribution of the sensor substrate and the deviation of the target temperature distribution of the sensor substrate.

3. The substrate processing method of claim 1, wherein the determining of the amount of change of the target temperature distribution of the heating plate comprises calculating a vector of a target temperature change value for each heating region of the heating plate to minimize a deviation of a vector of an expected temperature change value for each temperature control region of the sensor substrate, which is calculated by multiplying a matrix of the transfer coefficient and the vector of the target temperature change value for each heating region of the heating plate, and a vector of a target temperature change value for each temperature control region.

4. The substrate processing method of claim 3, wherein each of the plurality of substrate temperature sensors is located at a corresponding temperature control region of the sensor substrate.

5. The substrate processing method of claim 1, wherein the transfer coefficient is defined by experimental data obtained by measuring change in the temperature distribution of the sensor substrate according to change in temperature for each heating region of the heating plate.

6. The substrate processing method of claim 1, further comprising:
measuring the temperature distribution of the sensor substrate heated according to adjusted output of the heater;
determining whether or not the measured temperature distribution of the sensor substrate is included in a criteria range by comparing the measured temperature distribution of the sensor substrate and the target temperature distribution of the sensor substrate; and
re-adjusting the amount of change of the target temperature distribution of the heating plate when the measured temperature distribution of the sensor substrate is deviated from the criteria range.

7. The substrate processing method of claim 6, further comprising:
updating the transfer coefficient in response to the measured temperature distribution of the sensor substrate and the deviation of the target temperature distribution of the sensor substrate.

8. A thermal processing apparatus configured to perform thermal processing, the thermal processing apparatus comprising:
a heating plate provided in a circular shape to allow a substrate to be seated;
a heater configured to emit heat to heat the substrate;
a plate temperature sensor configured to measure temperature of the heating plate; and
a controller configured to control an output of the heater,
wherein the controller is configured to:
determine an output of the heater by using a sensor substrate comprising a plurality of substrate temperature sensors, and
perform thermal processing on the substrate in response to the output of the heater, and
wherein, in order to determine the output of the heater, the controller is further configured to:
heat the sensor substrate located at the heating plate through the heater,
measure a temperature distribution of the sensor substrate,
determine an amount of change of target temperature distribution of the heating plate, on the basis of a deviation of the measured temperature distribution of the sensor substrate and a target temperature distribution of the sensor substrate, and a transfer coefficient defining change in temperature of each temperature control region in the sensor substrate according to change in temperature of a specific heating region in the heating plate, and
determine the output of the heater in response to the amount of change of the target temperature distribution of the heating plate.

9. The thermal processing apparatus of claim 8, wherein the amount of change of the target temperature distribution of the heating plate is determined through the equation described below,
ΔT_{Heater}=KΔT_{wafer (K=(F}_{^{T}}_{F)}_{^{−1}}_{F}_{^{T}}₎
ΔT_{Heater} corresponds to the amount of change of the target temperature distribution of the heating plate, F is a matrix composed of the transfer coefficient, and ΔT_{wafer} corresponds to the measured temperature distribution of the sensor substrate and the deviation of the target temperature distribution of the sensor substrate.

10. The thermal processing apparatus of claim 8, wherein the controller is preset to calculate a vector of a target temperature change value for each heating region of the heating plate to minimize a deviation of a vector of an expected temperature change value for each temperature control region of the sensor substrate, which is calculated by multiplying a matrix of the transfer coefficient and the vector of the target temperature change value for each heating region of the heating plate, and a vector of a target temperature change value for each temperature control region.

11. The thermal processing apparatus of claim 10, wherein each of the plurality of substrate temperature sensors is located at a corresponding temperature control region of the sensor substrate.

12. The thermal processing apparatus of claim 8, wherein the transfer coefficient is defined by experimental data obtained by measuring change in the temperature distribution of the sensor substrate according to change in temperature for each heating region of the heating plate.

13. The thermal processing apparatus of claim 8, wherein the controller is preset
to measure the temperature distribution of the sensor substrate heated in response to an adjusted output of the heater,
to determine whether or not the measured temperature distribution of the sensor substrate is included in a criteria range by comparing the measured temperature distribution of the sensor substrate and the target temperature distribution of the sensor substrate, and
to re-adjust the amount of change of the target temperature distribution of the heating plate when the measured temperature distribution of the sensor substrate is deviated from the criteria range.

14. The thermal processing apparatus of claim 8, wherein the controller is preset to update the transfer coefficient in response to the measured temperature distribution of the sensor substrate and the deviation of the target temperature distribution of the sensor substrate.

15. A semiconductor manufacturing equipment comprising:
an index module configured to transfer a substrate from a container in which the substrate is received; and
a processing module comprising a bake unit performing thermal processing on the substrate,
wherein the bake unit comprises:
a heating plate provided in a circular shape to allow a substrate to be seated;
a heater configured to emit heat to heat the substrate;
a plate temperature sensor configured to measure temperature of the heating plate; and
a controller configured to control an output of the heater,
wherein the controller is configured to:
determine an output of the heater by using a sensor substrate comprising a plurality of substrate temperature sensors, and
perform thermal processing on the substrate in response to the output of the heater, and
wherein, in order to determine the output of the heater, the controller is further configured to:
heat the sensor substrate located at the heating plate through the heater,
measure a temperature distribution of the sensor substrate,
determine an amount of change of target temperature distribution of the heating plate, on the basis of a deviation of the measured temperature distribution of the sensor substrate and a target temperature distribution of the sensor substrate, and a transfer coefficient defining change in temperature of each temperature control region in the sensor substrate according to change in temperature of a specific heating region in the heating plate, and
determine the output of the heater in response to the amount of change of the target temperature distribution of the heating plate.

16. The semiconductor manufacturing equipment of claim 15, wherein the amount of change of the target temperature distribution of the heating plate is determined through the equation described below,
ΔT_{Heater}=KΔT_{wafer (K=(F}_{^{T}}_{F)}_{^{−1}}_{F}_{^{T}}₎
ΔT_{Heater} corresponds to the amount of change of the target temperature distribution of the heating plate, F is a matrix composed of the transfer coefficient, and ΔT_{wafer} corresponds to the measured temperature distribution of the sensor substrate and the deviation of the target temperature distribution of the sensor substrate.

17. The semiconductor manufacturing equipment of claim 15, wherein the controller is preset to calculate a vector of a target temperature change value for each heating region of the heating plate to minimize a deviation of an expected temperature change value for each temperature control region of the sensor substrate, which is calculated by multiplying a matrix of the transfer coefficient and the vector of the target temperature change value for each heating region of the heating plate, and a target temperature change value for each temperature control region.

18. The semiconductor manufacturing equipment of claim 17, wherein each of the plurality of substrate temperature sensors is located at a corresponding temperature control region of the sensor substrate.

19. The semiconductor manufacturing equipment of claim 15, wherein the transfer coefficient is defined by experimental data obtained by measuring change in the temperature distribution of the sensor substrate according to change in temperature for each heating region of the heating plate.

20. The semiconductor manufacturing equipment of claim 15, wherein the controller is preset
to measure the temperature distribution of the sensor substrate heated in response to an adjusted output of the heater,
to determine whether or not the measured temperature distribution of the sensor substrate is included in a criteria range by comparing the measured temperature distribution of the sensor substrate and the target temperature distribution of the sensor substrate,
to re-adjust the amount of change of the target temperature distribution of the heating plate when the measured temperature distribution of the sensor substrate is deviated from the criteria range, and
to update the transfer coefficient in response to the measured temperature distribution of the sensor substrate and the deviation of the target temperature distribution of the sensor substrate.
